(19) United States
(12) Patent Application Publication
(10) Pub. No.: US 2019/0363017 A1
(43) Pub. Date: Nov. 28, 2019

(54) DIE SAWING SINGULATION SYSTEMS AND METHODS

(71) Applicant: SEMICONDUCTOR COMPONENTS INDUSTRIES, LLC, Phoenix, AZ (US)

(72) Inventor: Michael J. SEDDON, Gilbert, AZ (US)

(73) Assignee: SEMICONDUCTOR COMPONENTS INDUSTRIES, LLC, Phoenix, AZ (US)

(21) Appl. No.: 15/988,718

(22) Filed: May 24, 2018

(51) Int. Cl. H01L 21/78; H01L 21/04

(52) U.S. Cl. CPC H01L 21/78; H01L 21/268; H01L 21/0475

(57) ABSTRACT

Implementations of a method of singulating a plurality of semiconductor die may include: forming a damage layer beneath a surface of a die street where the die street connects a plurality of semiconductor die and the plurality of semiconductor die are formed on a semiconductor substrate. The method may also include sawing the die street after forming the damage layer to singulate the plurality of semiconductor die.

### BACKGROUND

### 1. Technical Field

Aspects of this document relate generally to systems and methods for singulating die from semiconductor substrates including wafers.

### 2. Background

Semiconductor devices are typically formed on and into the surface of a semiconductor substrate. As the semiconductor substrate is typically much larger than the devices, the devices are singulated one from another into various semiconductor die. Sawing the semiconductor substrate is a method used to separate the semiconductor die from each other.

### SUMMARY

Implementations of a method of singulating a plurality of semiconductor die may include: forming a damage layer beneath a surface of a die street where the die street connects a plurality of semiconductor die and the plurality of semiconductor die are formed on a semiconductor substrate. The method may also include sawing the die street after forming the damage layer to singulate the plurality of semiconductor die.

Implementations of methods of singulating a plurality of semiconductor die may include one, all, or any of the following:

The semiconductor substrate may be silicon carbide.

Forming the damage layer may further include irradiating the die street with a laser beam at a focal point within the semiconductor substrate at one or more spaced apart locations beneath the surface of the die street to form the damage layer.

Forming the damage layer may further include irradiating the die street with a laser beam at a focal point at a first depth within the semiconductor substrate at one or more spaced apart locations beneath the surface of the die street. The method may further include irradiating the die street with a laser beam at a focal point at a second depth within the semiconductor substrate at one or more spaced apart locations beneath the surface of the die street.

The method further include, before sawing the die street, ablating at least a portion of the material of the die street using a laser.

The method may further include, before sawing the die street, ablating at least a majority of the material of the die street using a laser.

The method may further include, before sawing the die street, scribing a portion of the material of the die street using a stylus.

Implementations of a method of singulating a plurality of semiconductor die may include forming a damage layer beneath a surface of a die street where the die street connects a plurality of semiconductor die formed on a semiconductor substrate. The method may include sawing the die street while applying sonic energy during sawing after forming the damage layer to singulate the plurality of semiconductor die.

Implementations of a method of singulating a plurality of semiconductor die may include one, all, or any of the following:

Applying sonic energy may further include applying sonic energy between 20 kHz to 3 GHz to a spindle coupled with a saw blade performing the sawing of the die street.

The semiconductor substrate may be silicon carbide.

Forming the damage layer may further include irradiating the die street with a laser beam at a focal point within the semiconductor substrate at one or more spaced apart locations beneath the surface of the die street to form the damage layer.

Forming the damage layer may further include irradiating the die street with a laser beam at a focal point at a first depth within the semiconductor substrate at one or more spaced apart locations beneath the surface of the die street. The method may also include irradiating the die street with a laser beam at a focal point at a second depth within the semiconductor substrate at one or more spaced apart locations beneath the surface of the die street.

The method may include before sawing the die street, ablating at least a portion of the material of the die street using a laser.

The method may include before sawing the die street, ablating at least a majority of the material of the die street using a laser.

The method may include before sawing the die street, scribing a portion of the material of the die street using a stylus.

Implementations of a method of singulating a plurality of semiconductor die may include irradiating the die street with a laser beam at a focal point within the semiconductor substrate at one or more spaced apart locations beneath the surface of the die street to form a damage layer beneath a surface of the die street where the die street connects a plurality of semiconductor die formed on a silicon carbide semiconductor substrate. The method may include sawing the die street using a saw blade while applying sonic energy to a spindle coupled with the saw blade to singulate the plurality of semiconductor die.

Implementations of a method of singulating a plurality of semiconductor die may include one, all, or any of the following:

Applying sonic energy may further include applying sonic energy between 20 kHz to 3 GHz.

The method may include before sawing the die street, ablating at least a portion of the material of the die street using a laser.

The method may include before sawing the die street, scribing a portion of the material of the die street using a stylus.

Irradiating the die street with the laser beam may further include irradiating the die street with the laser beam at the focal point at a first depth within the semiconductor substrate at the one or more spaced apart locations beneath the surface of the die street. The method may further include irradiating the die street with the laser beam at a focal point at a second depth within the semiconductor substrate at one or more spaced apart locations beneath the surface of the die street.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of a laser beam irradiating a focal point beneath a surface of a street between a plurality of semiconductor die;

FIG. 2 a cross sectional view of a laser beam irradiating a focal point at a second depth beneath a surface of a street;

FIG. 3 is a cross sectional view of a street during sawing using a saw blade;

FIG. 4 is a cross sectional view of a street during sawing using a saw blade during application of sonic energy;

FIG. 5 is a top view of a street intersection following laser irradiation using two passes in both streets prior to saw singulation;

FIG. 6 is a diagram of a single pass laser irradiation process for a semiconductor substrate;

FIG. 7 is a diagram of a street intersection following laser irradiation using two passes in both streets after scribing the streets using a stylus;

FIG. 8 is a diagram of a street intersection following laser irradiation using two passes in both streets during laser ablation followed by cold gas treatment;

FIG. 9 is a cross sectional view of a street following formation of a damage layer followed by laser ablation of a majority of the material in the street;

FIG. 10 is a cross sectional view of the street of FIG. 9 during sawing using a saw blade;

FIG. 11 is a cross sectional view of a street following formation of a damage layer followed by laser ablation of a portion of the material in the street just prior to sawing using a saw blade.

### DESCRIPTION

This disclosure, its aspects and implementations, are not limited to the specific components, assembly procedures or method elements disclosed herein. Many additional components, assembly procedures and/or method elements known in the art consistent with the intended methods of singulating semiconductor die will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such methods of singulating semiconductor die, and implementing components and methods, consistent with the intended operation and methods.

A wide variety of semiconductor substrate types exist and are used in the process of manufacturing various semiconductor devices. Non-limiting examples of semiconductor substrates that may be processed using the principles disclosed in this document include single crystal silicon, silicon dioxide, glass, silicon-on-insulator, gallium arsenide, sapphire, ruby, silicon carbide, polycrystalline or amorphous forms of any of the foregoing, and any other substrate type useful for constructing semiconductor devices. Particular implementations disclosed herein may utilize silicon carbide semiconductor substrates (silicon carbide substrates) of any polytype. In this document the term “wafer” is also used along with “substrate” as a wafer is a common type of substrate, but not as an exclusive term that is used to refer to all semiconductor substrate types. The various semiconductor substrate types disclosed in this document may be, by non-limiting example, round, rounded, square, rectangular, or any other closed shape in various implementations.

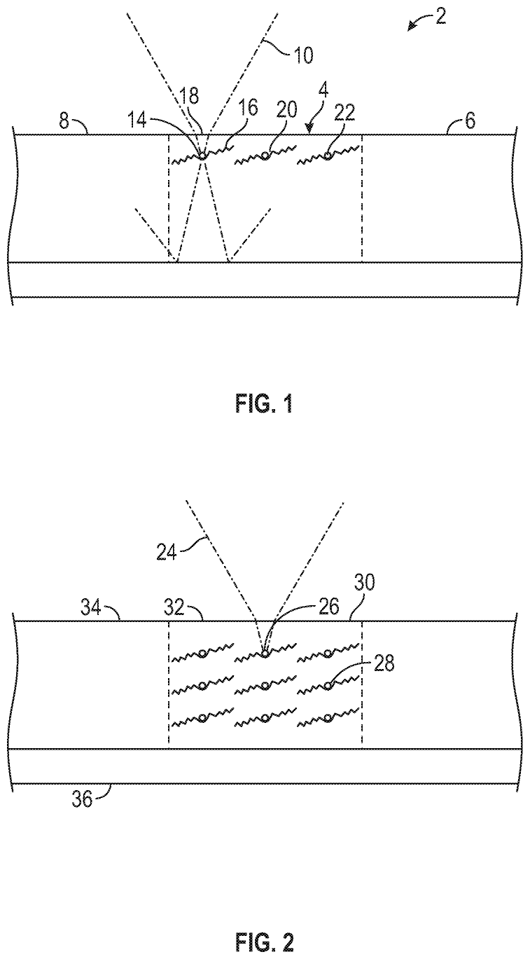

Referring to FIG. 1, a street region 4 of a semiconductor substrate 2 is illustrated. As illustrated, the street 4 is the area of the semiconductor substrate between die 6, and 8 and extends across the thickness of the semiconductor substrate. Since this is a cross sectional view, just two die 6, 8 are visible in this view, but the street extends across a plurality of die spaced apart across the surface of the semiconductor substrate 2. In this implementation, a laser beam 10 is irradiating the material of the street 4 at a focal point 14 beneath a surface 18 of the street 4. Because the laser beam 10 causes localized heating at the focal point 14, the structure of the material at the focal point is disrupted. The semiconductor substrate 2 illustrated in FIG. 1 is a single crystal silicon carbide substrate.

The degree of damage at the focal point is determined by many factors, including, by non-limiting example, the power of the laser light, the duration of exposure of the material, the absorption of the material of the substrate, the crystallographic orientation of the substrate material relative to the direction of the laser light, the atomic structure of the substrate, and any other factor regulating the absorbance of the light energy and/or transmission of the induced damage or heat into the substrate. The wavelength of the laser light used to irradiate the street 4 is one for which the material of the particular semiconductor substrate is at least partially optically transmissive, whether translucent or transparent. Where the substrate is a silicon carbide substrate, the wavelength may be 1064 nm. In various implementations, the laser light source may be a Nd:YAG pulsed laser or a YVO4 pulsed laser. In one implementation where a Nd:YAG laser is used, a spot size of 10 microns and an average power of 3.2 W may be used along with a repetition frequency of 80 kHz, pulse width of 4 ns, numerical aperture (NA) of the focusing lens of 0.45. In another implementation, a Nd:YAG laser may be used with a repetition frequency of 400 kHz, average power of 16 W, pulse width of 4 ns, spot diameter of 10 microns, and NA of 0.45. In various implementations, the power of the laser may be varied from about 2 W to about 4.5 W. In other implementations, however, the laser power may be less than 2 W or greater than 4.5 W.

As illustrated, the focal point 14 of the laser light forms a location of rapid heating and may result in full or partial melting of the material at the focal point 14. The point of rapid heating and the resulting stress on the hexagonal single crystal structure of the SiC substrate as a result of the heating/cooling results in cracking of the substrate material along a c-plane of the substrate. Depending on the type of single SiC crystal used to manufacture the boule, the c-plane may be oriented at an off angle to the second surface of about 1 degree to about 6 degrees. In various implementations, this angle is determined at the time the boule is manufactured. In particular implementations, the off angle may be about 4 degrees.

During operation, the laser is operated in pulsed operation to create numerous overlapping spots of pulsed light while passing across the surface of the substrate. As a result, a continuous/semi-continuous layer/band of modified material is formed within the wafer. In other implementations, the laser may be operated in continuous wave mode rather than pulsed mode to create the band of modified material. As illustrated, the stress caused by the focal point 14 causes cracking along the c-plane in the material of the street 4 in one or both directions along the c-plane. These cracks 16 are illustrated as spreading from the focal point 14 area (where the modified layer/band is located) angled at the off angle in FIG. 1. In various implementations, the cracks 16 may be located below the focal point 14, above the focal point 14, or spread directly from the focal point 14, depending on the characteristics of the laser and the method of application of the laser to the material. In various implementations, the length of the cracks 16 into the substrate is a function of the power of the laser applied. By non-limiting example, the depth of the focal point was set at 500 um into the substrate; where the laser power was 3.2 W, the crack propagation from the modified layer/band was about 250 um; where the laser power was at 2 W, the crack lengths were about 100 um; where the laser power was set at 4.5 W, the crack lengths were about 350 um.

As illustrated in FIG. 1, the laser beam 10 is in the processing of making a third pass along the street at a third spaced apart location from the two previous passes 20, 22. In various implementations, one, two, or more passes may be conducted in any street. The various passes may use the same laser parameters and feed speeds/rates or may be conducted using different laser parameters and different feed speeds/rates. The disrupted material and cracks from the laser irradiation form a damage layer beneath the surface 18 of the street 4. The damage layer breaks up the structure of the semiconductor substrate material (in the case of SiC, the hexagonal crystalline structure of the substrate) thereby weakening the strength of the material.

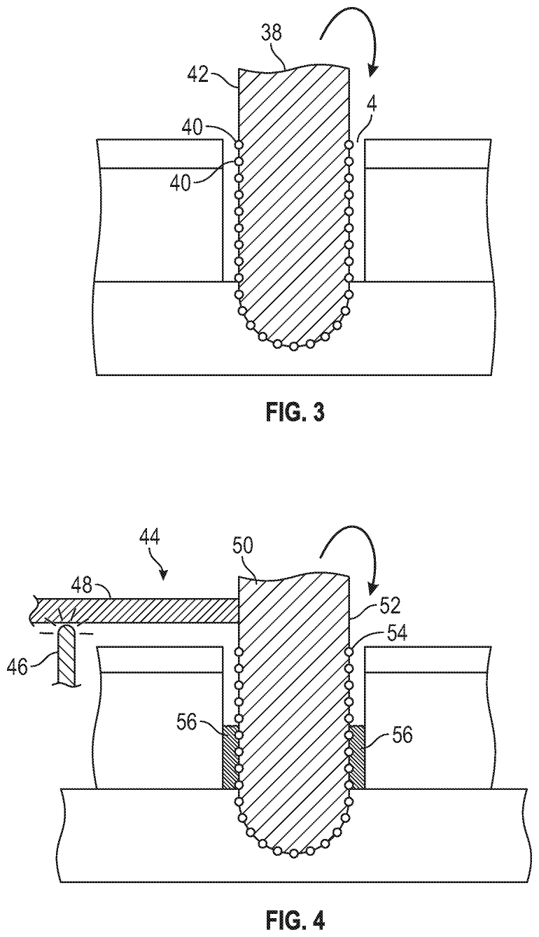

Referring to FIG. 2, a laser beam 24 is illustrated focused a focal point 26 at a second depth into the material of the street 30. Other focal points like focal point 28 are illustrated that are a different depth into the material of the street 30 (distance beneath the surface 32 of the street 30). In this way, multiple damage layers can be formed within the material of the street 30. Generally, the damage layer at the deepest depth into the material of the street would be formed first, followed by the next damage layer, and so forth. However, in other implementations, the reverse may be done, particularly where the focal points do not directly overlap each other but are staggered instead. As illustrated, the irradiation is being conducted from the back side 34 of the substrate, or the side of the substrate that is opposite the side on which the semiconductor devices have been formed (device side 36). In other implementations, however, depending on the material in the street, the laser irradiation can be performed from the device (front) side 36 of the substrate. Where laser irradiation is conducted from the back side 34 of the substrate, the use of back side cameras to align the wafer using the device side of the wafer may be used to align the wafer to ensure that the laser irradiation is properly aligned with the streets themselves and avoids the area of the plurality of die.

Following formation of the damage layer, FIG. 3 illustrates the removal of the material in the street 4 using saw blade 38. As illustrated, the sawing of the substrate takes place once the substrate has been mounted on cutting tape and flipped device side up from the orientation in FIGS. 1 and 2. As illustrated, the saw blade 38 is made of a composite material that includes a binding matrix 42 that holds particles of diamond grit 40 therein. During the sawing process, the material of the matrix 42 wears away exposing the diamond grit 40 particles, which also eventually fall out of their place in the blade after being used to the sawing process for a time. In this way, fresh diamond particles are constantly being exposed and available for use during the entire lifetime of the blade. The damage layers weaken the crystal structure of the semiconductor substrate, and so allow the blade to remove the material in the street more easily. Since the material is easier to remove, then less wear on the blade occurs and the blade lifetime can be increased. Also, in some implementations, the saw process may be able to take place more quickly since the material can be removed more quickly. Since the saw blade is a consumable as it wears over time and requires changing, increasing the blade lifetime and/or increasing the number of substrates which can be cut using the saw blade can reduce the processing cost per substrate.

During the sawing process, particularly for hard substrates, the saw blade can glaze or otherwise prevent the material of the matrix from properly abrading (due to accumulation of material from the cutting tape and/or material from the substrate being sawn), causing the blade to no longer be bringing new diamond grit particles to the surface of the blade. This reduces the effectiveness of the blade when cutting, decreasing cutting speed and/or causing increased sidewall damage to the die, which can reduce die strength, particularly for thinned die. Referring to FIG. 4, an implementation of a sonic energy assisted sawing system 44 is illustrated. As illustrated, a sonic energy source 46 is coupled with a spindle 48 that is rotatably coupled with saw blade 50. During operation, the sonic energy from the sonic energy source 46 is transmitted down the spindle 48 as vibrational energy causing the saw blade 50 to correspondingly vibrate during operation. As a result, the matrix 52 vibrates against the material of the substrate being cut and abrades more easily, allowing fresh pieces of diamond grit to be more readily exposed. Also, as illustrated in FIG. 4, the sawn slurry material 56 of the substrate itself can act as grit against the blade 50 due to the vibration action and also assist in the cutting process of unsawn substrate material as well. The observed effect of sonic energy enhanced sawing is that the sawing process proceeds more quickly, blade lifetimes are longer, and/or the sidewall damage observed following the sawing process is reduced. Also, for substrates where the Mohs hardness of the material being sawn is close to the hardness of the diamond grit (like silicon carbide), the benefits of using sonic enhanced singulation may be particularly advantageous, due to the generally slow sawing process and high blade wear rates observed for such materials. The effect of the increased efficiency of the cutting processing where sonic energy is applied to the spindle can be observed in lower spindle currents being required during the sawing process.

A wide variety of frequencies may be employed by the source of sonic energy 46 which may range from about 20 kHz to about 3 GHz. Where the sonic frequencies utilized by the ultrasonic energy source 40 are above 360 kHz, the energy source may also be referred to as a megasonic energy source. In particular implementations, the sonic energy source 46 may generate ultrasonic vibrations at a frequency of 40 kHz at a power of 80 W. In various implementations, the sonic energy source 46 may apply a frequency of between about 30 kHz to about 50 kHz or about 35 kHz to about 45 kHz. However, in various implementations, frequencies higher than 50 kHz may be employed, including megasonic frequencies. A wide variety of power levels may also be employed in various implementations.

The sonic energy source 46 may employ a wide variety of transducer/oscillator designs to generate and transfer the sonic energy to the spindle in various implementations, including, by non-limiting example, magnetostrictive transducers and piezoelectric transducers. In the case where a magnetostrictive transducer/oscillator is utilized, the transducer utilizes a coiled wire to form an alternating magnetic field inducing mechanical vibrations at a desired frequency in a material that exhibits magnetostrictive properties, such as, by non-limiting example, nickel, cobalt, terbium, dysprosium, iron, silicon, bismuth, aluminum, oxygen, any alloy thereof, and any combination thereof. The mechanical vibrations are then transferred to the portion of the ultrasonic energy source that contacts the liquid. Where a piezoelectric transducer/oscillator is employed, a piezoelectric material is subjected to application of electric charge and the resulting vibrations are transferred to the portion of the ultrasonic energy source that contacts the liquid. Example of piezoelectric materials that may be employed in various implementations include, by non-limiting example, quartz, sucrose, topaz, tourmaline, lead titanate, barium titanate, lead zirconate titanate, and any other crystal or material that exhibits piezoelectric properties.

Saw singulation processes that employ sonic energy enhancement may be used in various methods of die singulation disclosed in this document that involve use of damage layers in streets. In other implementations, however, the sonic energy enhancement may not be used.

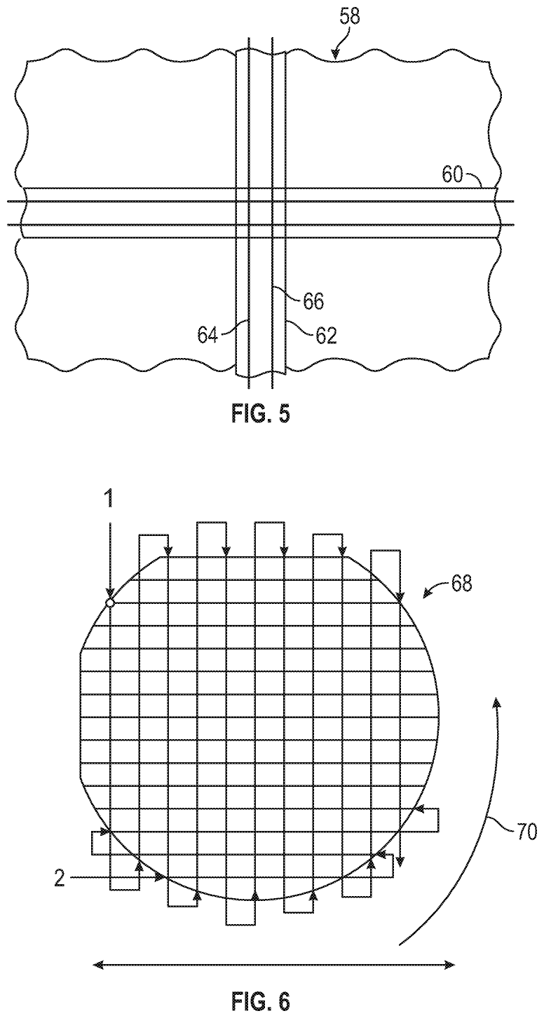

Referring to FIG. 5, a top down view of an implementation of a street intersection 58 is illustrated following processing using a two pass laser irradiation process in each intersecting street 60, 62 that forms two continuous/semicontinuous damaged regions 64, 66 that form the damage layer in each street 60, 62. A wide variety of techniques can be employed in various method implementations to form the damage layer including single pass, dual pass, three pass, or more than three pass laser irradiation processes. Also, a wide variety of laser beam configurations may be used in conducting the various passes at various depths. For example, a single laser beam could be used to irradiate the streets at a single depth in some implementations. In others, two or more laser beams could be used to irradiate a street at a single depth or at different depths. Also, laser beams of, by non-limiting example, differing types, powers, numerical apertures, spot sizes, repetition rates, pulse rates, may be employed in making any or all of the passes in laser irradiation implementations disclosed in this document. While the passes are shown as having effects visible on the surface of the street in various implementations, the damage to the subsurface material of the street may not be visible at all at the surface.

FIG. 6 illustrates an implementation of a single pass laser irradiation process where the laser begins irradiation at the point marked 1 and continues in an alternating fashion to index over each vertically aligned street in the wafer 68 while the wafer moves horizontally. In various implementations, the laser can then begin irradiation over the wafer's horizontal streets beginning at the point marked 2 and continuing in an alternating fashion to index over each horizontally aligned street in the wafer while the wafer moves vertically. In some implementations, however, as indicated by the rotational arrow 70 in FIG. 6, after the laser has irradiated the vertical streets starting at 1, the wafer can be rotated 90 degrees and the previously horizontal streets may be irradiated without requiring the wafer stage to move in the horizontal direction. This could improve run rates or reduce tool equipment size in various implementations. Many possible laser pass arrangements, pass patterns, and tool configurations are possible using the principles disclosed in this document. The wafer in FIG. 6 is a silicon carbide wafer as indicated by the presence of the two wafer flats.

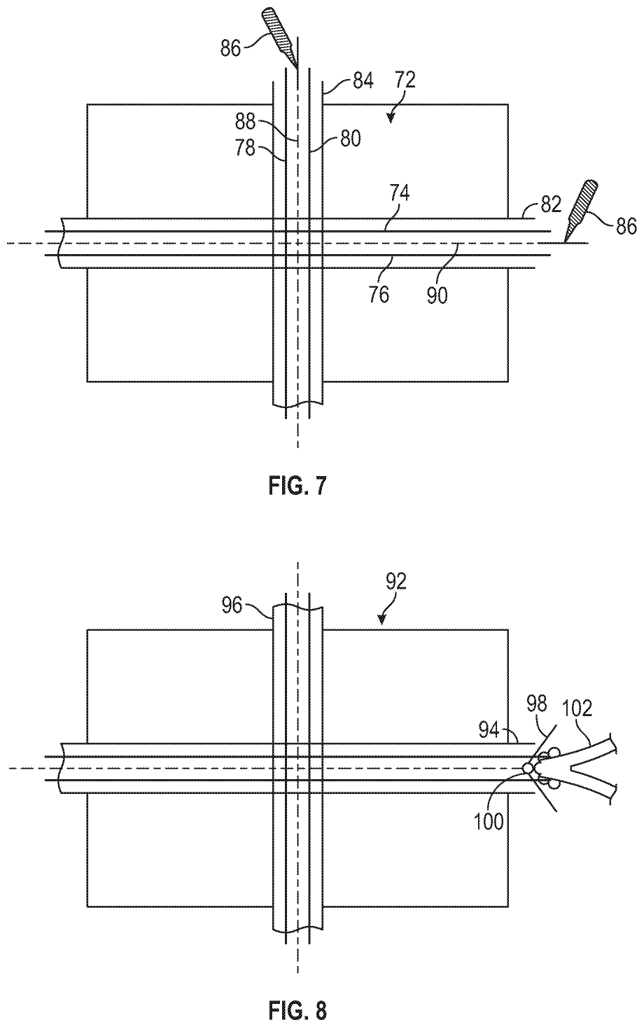

Other techniques in addition to sawing to displace or affect the material in the streets may be employed in combination with the creation of a damage layer through laser irradiation. Referring to FIG. 7, an implementation of a street intersection 72 is illustrated following two pass laser irradiation 74, 76, 78, 80 to form a damage layer in each street 82, 84. Following the irradiation, a stylus 86 is then drawn across the material of each street 84, 86 to form a scribe mark 88, 90. Depending on the pressure, speed, and/or tip characteristics of the stylus 86, the scribe mark may result in removal of material from the street and/or the formation of a crack that propagates down into the material of the street from the scribe mark following the crystal structure of the semiconductor substrate. In some implementations, following creation of the scribe mark in each street, the substrate can be stretched or flexed through mounting the substrate is onto cutting tape or die attach film and stretching the film. In this way, the cracks formed by the scribe mark then complete propagating through the thickness of the substrate thus singulating the plurality of die which can then be picked from the tape. The ability for the scribe mark to create a crack capable of permitting direct scribe and break separation using a process like this depends on the crystallographic orientation of the crystal planes of the particular semiconductor substrate being used (and whether the substrate is a single crystal substrate or not). In some substrates, since the crack will follow the path of least resistance, the crack may actually attempt to propagate at some angle from the scribe mark into the die. In such implementations, the scribe mark may simply be used as a material removal/additional street damage technique to aid in further damaging the material in the street and/or removing material before sawing using a saw blade using any of the techniques disclosed in this document. The use of the scribing technique may improve die strength as it may reduce the amount of material sawn or eliminate the need for saw, depending on the crystallography of the particular semiconductor substrate.

While the use of a stylus to create a scribe mark across the entire street is illustrated in FIG. 7, in other implementations, the stylus may be passed over only a portion of each street, or just passed over the edge(s) of each street. These implementations generally rely on the resulting scribe mark to form a crack that propagates along the crystal planes through the rest of the material of the street. Such implementations may also be combined with the various sawing implementations disclosed herein.

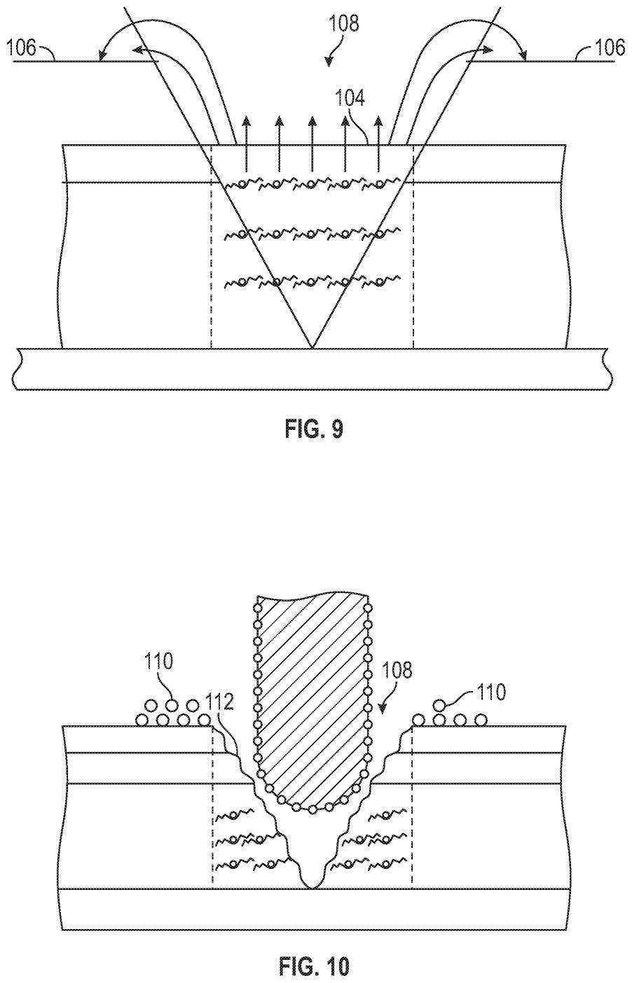

Referring to FIG. 8, an implementation of a street intersection 92 is illustrated following a two pass laser irradiation process down each street 94, 96 that creates a damage layer under the surface of the material of the street like any disclosed herein. As illustrated, following creating of the damage layer, a laser beam 98 configured to ablate the material of the street using, by non-limiting example, a particular laser type, beam width, pulse energy, repetition rate, power, and any other laser parameter may be passed across the material of the street. Also, in some implementations, a jet of gas 102 may be applied at the focal point 100 of the ablation laser beam. In some implementations, this jet of gas may be at ambient temperature and designed to blow the slag from the laser in a desired direction either out of the laser beam or relative to the street. In other implementations, the jet of gas may be cooled relative to ambient temperature and/or a temperature of the substrate and may act to thermally shock the substrate at the point at or close behind the heated ablation point. In these implementations, the remaining material of the street may fracture along the crystallographic plane of least resistance and result in singulation of the die on each side of the street from each other. Where cold gas is used, less ablation by the laser may be needed to achieve singulation of the die, which can reduce the amount of slag deposited on the die and/or increase the ultimate die strength following singulation.

For those implementations where the die is not singulated using the laser ablation (either directly by the laser or through the use of cold gas treatment following laser ablation), the amount of material to be sawn is correspondingly reduced. Also, since the sawing process will tend to clean up the ablated edges of the die, following the laser ablation process with a saw process may increase the saw blade lifetime and speed of the process while increasing the die strength relative to a full laser ablation process. FIG. 9 illustrates a typical die sidewall profile of a street 108 following a full singulation laser ablation process through a laser damaged street as it is being conducted following a three pass, three level laser irradiation process. As illustrated, the material of the damage layer vaporizes and/or comes out of the street as molten slag and redeposits on the adjoining die on each side of the street. Because of this, as illustrated in FIG. 9, a temporary coating 106 of material may be deposited over the substrate prior to laser ablation on which the slag deposits. Following the completion of the laser ablation process, the temporary coating 106 may be removed through a washing or other removal process, thus eliminating the slag from the die surfaces.

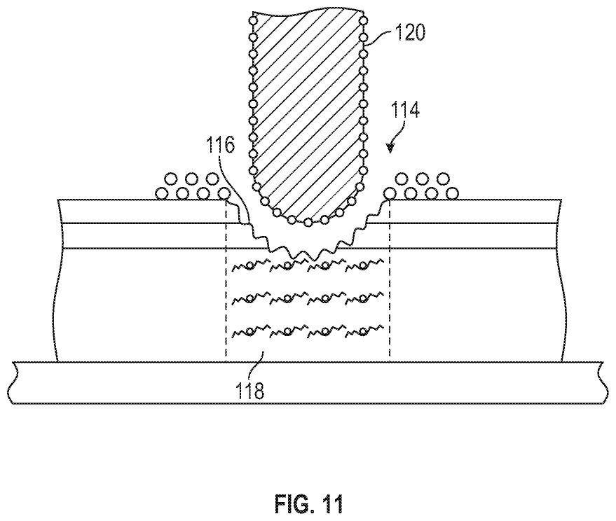

FIG. 10 illustrates the street 108 where the laser ablation process has been completed, and the slag 110 has been deposited on each side. As illustrated, the resulting cut by the laser is not smooth but typically results in a rather jagged and rough profile 112. Here a saw blade (which may be sonic energy assisted or not in various implementations) is being inserted into the street during the saw process to remove the remaining material of the damage layer of the street and complete the singulation of the plurality of die on each side. As illustrated, the ablation process has removed material substantially through the thickness of the street (a majority of the material of the die street). However, in other laser ablation processes, the parameters of the laser ablation process may be set so that only the material that forms the stack of the semiconductor device formed on the semiconductor device may be removed, as illustrated in FIG. 11. FIG. 11 illustrates a street 114 following such an ablation process which has removed the material of the stack 116, but left most of the underlying semiconductor substrate material in the street 118 undamaged (removed only a portion of the material of the die street). A saw blade 120 is illustrated just prior to sawing of the street 114 which includes a damage layer previously created through a four pass, three level laser irradiation process. The sawing process may then be carried out with or without sonic energy enhancement as disclosed herein. The ability to laser ablate just the material of the stack may result in an ablation process with better control and reduced slag while speeding the saw process in various implementations.

In places where the description above refers to particular implementations of die singulation methods and implementing components, sub-components, methods and sub-methods, it should be readily apparent that a number of modifications may be made without departing from the spirit thereof and that these implementations, implementing components, sub-components, methods and sub-methods may be applied to other die singulation methods.

1. A method of singulating a plurality of semiconductor die, the method comprising:
forming a damage layer beneath a surface of a die street, the die street connecting a plurality of semiconductor die, the plurality of semiconductor die formed on a semiconductor substrate;
ablating at least a portion of the material of the die street using a laser; and
sawing the die street after forming the damage layer to singulate the plurality of semiconductor die.

2. The method of claim 1, wherein the semiconductor substrate is silicon carbide.

3. The method of claim 1, wherein forming the damage layer further comprises irradiating the die street with a laser beam at a focal point within the semiconductor substrate at one or more spaced apart locations beneath the surface of the die street to form the damage layer.

4. The method of claim 1, wherein forming the damage layer further comprises:
irradiating the die street with a laser beam at a focal point at a first depth within the semiconductor substrate at one or more spaced apart locations beneath the surface of the die street; and
irradiating the die street with a laser beam at a focal point at a second depth within the semiconductor substrate at one or more spaced apart locations beneath the surface of the die street.

5. (canceled)

6. The method of claim 1, further comprising before sawing the die street, ablating at least a majority of the material of the die street using a laser.

7. The method of claim 1, further comprising before sawing the die street, scribing a portion of the material of the die street using a stylus.

8. A method of singulating a plurality of semiconductor die, the method comprising:
forming a damage layer beneath a surface of a die street, the die street connecting a plurality of semiconductor die, the plurality of semiconductor die formed on a semiconductor substrate; and
sawing the die street while applying sonic energy between 20 kHz to 3 GHz to a spindle coupled with a saw blade performing the sawing of the die street after forming the damage layer to singulate the plurality of semiconductor die.

9. (canceled)

10. The method of claim 8, wherein the semiconductor substrate is silicon carbide.

11. The method of claim 8, wherein forming the damage layer further comprises irradiating the die street with a laser beam at a focal point within the semiconductor substrate at one or more spaced apart locations beneath the surface of the die street to form the damage layer.

12. The method of claim 8, wherein forming the damage layer further comprises:
irradiating the die street with a laser beam at a focal point at a first depth within the semiconductor substrate at one or more spaced apart locations beneath the surface of the die street; and
irradiating the die street with a laser beam at a focal point at a second depth within the semiconductor substrate at one or more spaced apart locations beneath the surface of the die street.

13. The method of claim 8, further comprising before sawing the die street, ablating at least a portion of the material of the die street using a laser.

14. The method of claim 8, further comprising before sawing the die street, ablating at least a majority of the material of the die street using a laser.

15. The method of claim 8, further comprising before sawing the die street, scribing a portion of the material of the die street using a stylus.

16. A method of singulating a plurality of semiconductor die, the method comprising:
irradiating the die street with a laser beam at a focal point within the semiconductor substrate at one or more spaced apart locations beneath the surface of the die street to form a damage layer beneath a surface of the die street, the die street connecting a plurality of semiconductor die, the plurality of semiconductor die formed on a silicon carbide semiconductor substrate; and
sawing the die street using a saw blade while applying sonic energy between 20 kHz to 3 GHz to a spindle coupled with the saw blade to singulate the plurality of semiconductor die.

17. (canceled)

18. The method of claim 16, further comprising before sawing the die street, ablating at least a portion of the material of the die street using a laser.

19. The method of claim 16, further comprising before sawing the die street, scribing a portion of the material of the die street using a stylus.

20. The method of claim 16, wherein irradiating the die street with the laser beam further comprises irradiating the die street with the laser beam at the focal point at a first depth within the semiconductor substrate at the one or more spaced apart locations beneath the surface of the die street; and
irradiating the die street with the laser beam at a focal point at a second depth within the semiconductor substrate at one or more spaced apart locations beneath the surface of the die street.
